(19) United States
(12) Patent Application Publication
(10) Pub. No.: US 2022/0254406 A1
(43) Pub. Date: Aug. 11, 2022

(54) NON-VOLATILE MEMORY CIRCUIT, SEMICONDUCTOR DEVICE, AND METHOD OF READING NON-VOLATILE MEMORY

(71) Applicant: LAPIS Technology Co., Ltd., Yokohama-shi (JP)

(72) Inventor: Takuya MATSUMOTO, Yokohama-shi (JP)

(73) Assignee: LAPIS Technology Co., Ltd., Yokohama-shi (JP)

(21) Appl. No.: 17/592,044

(22) Filed: Feb. 3, 2022

(30) Foreign Application Priority Data
Feb. 8, 2021 (JP) 2021-018403

(51) Int. Cl. G11C 11/4096; G11C 11/4074; G11C 11/4072; G11C 11/4076; G11C 29/44

(52) U.S. Cl. CPC G11C 11/4096; G11C 11/4074; G11C 29/4401; G11C 11/4076; G11C 11/4072

(57) ABSTRACT

A non-volatile memory circuit includes: a first memory including a plurality of cells that store values by respectively having elements whose states change physically due to application of a voltage from an exterior, a second memory including a plurality of cells that store values by respectively having the elements, a detector that, at a time of reading from the first memory, judges a value stored in each of the cells by comparing a threshold value and current values from the plurality of cells and a judging circuit supplying current of a predetermined current value to the detector as the threshold value.

### CROSS-REFERENCE TO RELATED APPLICATION

This application is based on and claims priority under 35 USC 119 from Japanese Patent Application No. 2021-018403 filed on Feb. 8, 2021, the disclosure of which is incorporated by reference herein.

### BACKGROUND

### Technical Field

The present disclosure relates to a non-volatile memory circuit, a semiconductor device, and a method of reading a non-volatile memory.

### Related Art

As disclosed in Japanese Patent Application Laid-Open (JP-A) No. 2003-204069 for example, in a Zener zap element, a zap diode is structured such that a P well region is formed at the surface layer of an N semiconductor layer, and a P anode region and an N cathode region are formed within the P well region, and an anode electrode and a cathode electrode are connected to the P anode region and the N cathode region respectively. Due to reverse bias voltage that is greater than or equal to the breakdown voltage being applied to the zap diode, the PN junction breaks-down, and the region between the anode electrode and the cathode electrode short-circuits, and the Zener zap element functions as a resistor.

JP-A No. 2013-222474 is an example of a technique of a non-volatile memory circuit that uses this Zener zap element as a storage unit for one bit. JP-A No. 2013-222474 discloses a technique of avoiding an increase in the surface area and an increase in the read time that accompany enlarging of the capacity of a non-volatile memory circuit that uses a Zener zap element.

In a non-volatile memory circuit that uses a Zener zap element, at the time of reading data, it is judged which of two values (“0” or “1”) the data is, in accordance with whether or not the value of the current that flows through the Zener zap element is greater than or equal to a threshold value. However, in a non-volatile memory circuit that uses an existing Zener zap element, the threshold value is set by a laser repair process, and there is dispersion in the values of the resistance that set the threshold value, and there are cases in which an expected threshold value cannot be set.

### SUMMARY

A non-volatile memory circuit according to an aspect of the present disclosure includes: a first memory including a plurality of cells that store values by respectively having elements whose states change physically due to application of a voltage from an exterior, a second memory including a plurality of cells that store values by respectively having the elements, a detector that, at a time of reading from the first memory, judges a value stored in each of the cells by comparing a threshold value and current values from the plurality of cells, and a judging circuit supplying current of a predetermined current value to the detector as the threshold value, wherein input terminals of the plurality of cells of the first memory are connected in common so as to be connected to a power supply for writing that supplies a voltage at a time of writing data to the plurality of cells, or a power supply for reading that supplies a voltage at a time of reading data from the plurality of cells, output terminals of the plurality of cells of the first memory are connected in common to an input terminal of the detector that judges a value stored in each of the cells based on current values from the plurality of cells, when reading from the first memory, due to selection instructing signals that select individual cells of the plurality of cells being inputted successively to the input terminals that are included respectively in the plurality of cells at a point in time when a predetermined time period has elapsed from supplying of the voltage of the power supply for reading, the output terminals of the plurality of cells that are selected are connected to the input terminal of the detector, and data, which sets the threshold value that is used in judgment by the detector, is stored in the second memory.

### BRIEF DESCRIPTION OF THE DRAWINGS

Exemplary embodiments of the present disclosure will be described in detail based on the following figures, wherein:

FIG. 1 is a drawing showing an example of the circuit structure of a non-volatile memory circuit relating to a first embodiment of the present disclosure;

FIG. 2 is a drawing showing an example of details of a unit cell of a second storage section;

FIG. 3 is a drawing showing an example of the circuit structure of a reference-for-judgment supplying circuit;

FIG. 4 is a drawing showing an example of the assigning of an address map of the non-volatile memory circuit relating to the first embodiment;

FIG. 5 is a flowchart showing an example of a method of writing TRM data in the non-volatile memory circuit relating to the first embodiment;

FIG. 6 is a flowchart showing an example of a method of reading user data, after the writing of TRM data in the non-volatile memory circuit relating to the first embodiment;

FIG. 7 is a drawing showing an example of the circuit structure of a non-volatile memory circuit relating to a second embodiment of the present disclosure;

FIG. 8 is a drawing showing an example of details of a unit cell of a third storage section;

FIG. 9 is a drawing showing an example of the assigning of an address map of the non-volatile memory circuit relating to the second embodiment;

FIG. 10 is a flowchart showing an example of a method of writing TRM data in the non-volatile memory circuit relating to the second embodiment;

FIG. 11 is a flowchart showing an example of a method of reading user data, after the writing of TRM data in the non-volatile memory circuit relating to the second embodiment;

FIG. 12 is a drawing showing the circuit structure of a conventional non-volatile memory circuit;

FIG. 13 is a drawing showing an example of details of a unit cell of a first storage section;

FIG. 14 is a drawing showing an example of the circuit structure of a reference-for-judgment supplying circuit;

FIG. 15 is a flowchart showing an example of a method of setting a trimming table in a trimming resistance method in the conventional non-volatile memory circuit; and

FIG. 16 is a drawing showing an example of the structure of a semiconductor device that uses the non-volatile memory circuit relating to the first embodiment or the second embodiment.

### DETAILED DESCRIPTION

Examples of embodiments of the present disclosure are described hereinafter with reference to the drawings. Note that structural elements and portions that are the same or equivalent in the respective drawings are denoted by the same reference numerals. Further, dimensional proportions in the drawings are depicted in an exaggerated manner for convenience of explanation, and may differ from actual proportions.

In the following explanation, a storage circuit using a Zener zap element is called a “ZapFuse”.

(Related Technology) Related technology on which the embodiments are premised is described here before entering into description of examples of embodiments of the present disclosure.

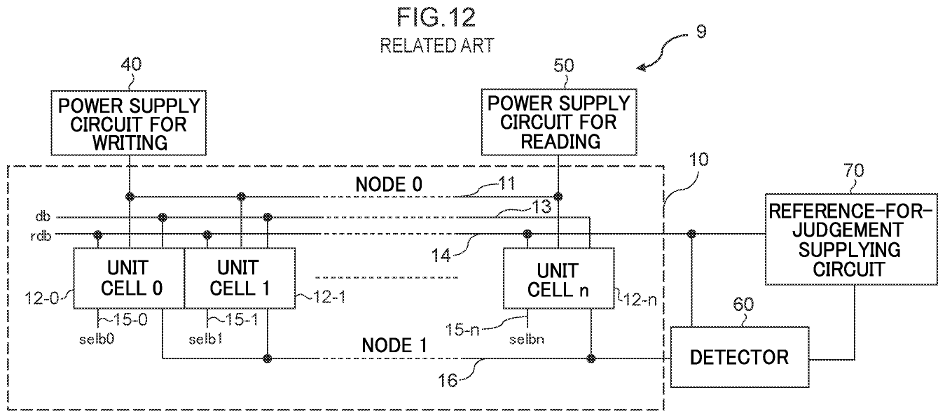

FIG. 12 is a drawing showing the circuit structure of a conventional non-volatile memory circuit.

Non-volatile memory circuit 9 that is shown in FIG. 12 has a power supply circuit 40 for writing, a power supply circuit 50 for reading, a power supply line 11 (also called node 0 hereinafter) for selectively supplying voltage for writing data from the power supply circuit 40 for writing or voltage for reading data from the power supply circuit 50 for reading, unit cells 12-0-12-n that are respectively connected in parallel between the power supply line 11 and an unillustrated reference power supply line that is connected to ground level, and that serve as n+1 (n is an integer of 1 or more) storage element portions that store data of 1 bit, signal lines 13, 14, 15-0-15-n that input respective signals (db, rdb, selb0-selbn), which have been inputted from a control section provided at the exterior, to the respective unit cells 12-0-12-n; a detector 60 to which output currents from the unit cells 12-0-12-n are inputted via an output line (also called node 1 hereinafter) 16 at the time of reading data, and a reference-for-judgment supplying circuit 70 that supplies reference current for judgment to the detector 60. A first storage section 10 is structured by the power supply line 11, the unit cells 12-0-12-n, the signal lines 13, 14, 15-0-15-n, and the output line 16.

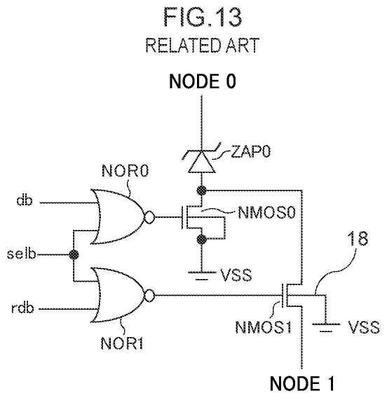

The respective units cells 12-0-12-n, which serve as storage element portions and are provided at the non-volatile memory circuit 9 in FIG. 12, have the same structure, and therefore, one unit cell is described with reference to FIG. 13.

Each of the unit cells has a Zener zap element ZAP0 whose cathode is connected to node 0 (the power supply line 11), a transistor NMOS0 that is formed from an NMOS transistor, and that is connected to the anode of the Zener zap element ZAP0, and that, at the time of writing data, connects the Zener zap element ZAP0 to the reference power supply line of reference potential VSS that is ground level, and a transistor NMOS1 that is formed from an NMOS transistor, and that is connected to the anode of the Zener zap element ZAP0, and that, at the time of reading data, connects the Zener zap element ZAP0 to node 1 (the output line 16). Moreover, in the structure shown in FIG. 13, the unit cell has NOR circuit NOR0 and NOR circuit NOR1 that control the transistor NMOS0 and the transistor NMOS1 in accordance with the data writing operation or the data reading operation.

The unit cell, which serves as a storage element portion of one bit, has one Zener zap element, two Zener zap element selecting transistors, and two NOR gates.

Signal db in FIG. 13 is a write instructing signal. Signal selbk is a select instructing signal for selecting the kth (0≤k≤n) unit cell. Signal rdb is a read instructing signal. These respective instructing signals are inputted from the exterior of the non-volatile memory circuit 9 to respective terminals of the NOR circuit NOR0 and the NOR circuit NOR1 via the signal line 13, the signal line 15-k and the signal line 14 that are shown in FIG. 12. Further, the transistor NMOS0 and the transistor NMOS1 are N-channel MOS transistors, and the reference potential VSS is ground level (ground).

The cathode of the Zener zap element ZAP0 is connected to the power supply line (node 0), and the anode is connected in common to the respective drains of the transistor NMOS0 and the transistor NMOS1.

The gate of the transistor NMOS0 is connected to the output terminal of the NOR circuit NOR0, and the source is connected to the reference potential VSS (ground level) via the reference power supply line 18. The gate of the transistor NMOS1 is connected to the output terminal of the NOR circuit NOR1, and the source is connected to the output line (node 1) 16.

Signal db is inputted to one input terminal of the NOR circuit NOR0. The another input terminal is connected in common with one input terminal of the NOR circuit NOR1, and signal selbk is inputted thereto. Further, signal rdb is inputted to the another input terminal of the NOR circuit NOR1.

Before writing, the Zener zap element ZAP0 operates as a diode, and therefore, current does not flow from the cathode to the anode. After writing, the Zener zap element ZAP0 shorts, and therefore, current flows from the cathode to the anode. At the time of reading data from the Zener zap element ZAP0, voltage for reading (hereinafter also called IVC) that is lower than the power supply voltage is applied to the cathode, and the current that flows to Zener zap element ZAPk is detected, and data is read. Further, at the time of writing data of the Zener zap element ZAP0, voltage for writing (hereinafter also called HV) that is higher than the power supply voltage is applied to the cathode, and data is written due to Zener breakdown.

Signal selbk is ground level (hereinafter also called L) at the time of selecting the kth Zener zap element ZAP0, and is power supply voltage level (hereinafter also called H) at times of non-selection. Signal db is L at times of writing the Zener zap element ZAP0, and is H at other times. Signal rdb is L at times of reading the Zener zap element ZAP0, and is H at other times.

Node 0 (the power supply line 11) is IVC at times of reading, and is HV at times of writing, and is ground level at times other than times of reading and times of writing. At the time of reading, node 1 (the output line 16) is the input voltage level of the detector 60 that is around 0.3 V, and, at times other than reading, is ground level.

The non-volatile memory circuit 9 of FIG. 12 has a structure in which n+1 of the unit cells that are shown in FIG. 13 are connected in parallel between the power supply line 11 (node 0) and the output line 16 (node 1).

The power supply circuit 40 for writing is a circuit that supplies voltage for writing (HV) from an external power supply at the time of writing the Zener zap element. The power supply circuit 50 for reading is a circuit that supplies voltage for reading (IVC) from an external power supply at the time of reading the Zener zap element. The detector 60 is a circuit that detects the current flowing through the Zener zap element, and converts the current into voltage.

The signal line 13, through which signal db is transferred in FIG. 12, is connected in common to the terminals, to which signal db is inputted at the NOR circuit NOR0 that is exemplified in FIG. 13, of the respective unit cells 12-0-12-n. Further, the signal lines 15-0-15-n, through which signals selb0-selbn in FIG. 12 are transferred, are connected to the respective terminals, to which signal selbk is inputted at the NOR circuit NOR0 and the NOR circuit NOR1 that are exemplified in FIG. 13, of the respective unit cells 12-0-12-n. Further, the signal line 14, through which signal rdb in FIG. 12 is transferred, is connected in common to the terminals, to which signal rdb is inputted at the NOR circuit NOR1 that is exemplified in FIG. 13, of the unit cells 12-0-12-n.

The power supply line 11 is connected in common to the respective unit cells 12-0-12-n, as node 0 that is exemplified in FIG. 13. Further, the output line 16 is connected in common to the respective unit cells 12-0-12-n and to the detector 60.

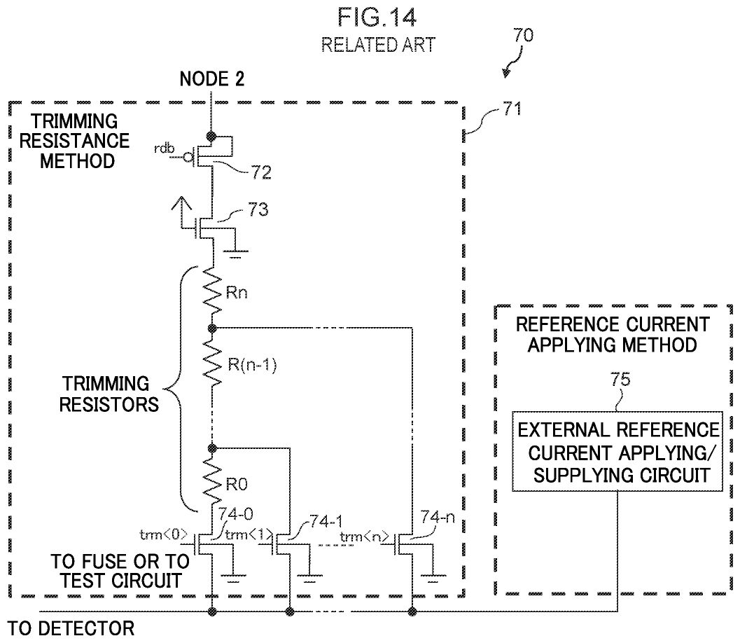

FIG. 14 is a drawing showing an example of the circuit structure of the reference-for-judgment supplying circuit 70. The reference-for-judgment supplying circuit 70 supplies reference current to the detector 60 from an electric power supplying section 71 or an external reference current applying/supplying circuit 75. The electric power supplying section 71 is formed from a PMOS transistor 72, an NMOS transistor 73, trimming resistors R0-Rn, and NMOS transistors 74-0-74-n.

When L is inputted to rdb in FIG. 14, the PMOS transistor 72 turns on, and the potential of IVC, which is similar to node 0 of the power supply circuit 50 for reading, is supplied to node 2, and the current that flows through the trimming resistors R0-Rn is supplied to the detector 60. In a case in which the current that is outputted from the respective unit cells 12-0-12-n is smaller than this current value, the data is judged to be “0” at the detector 60, and, in a case in which the current that is outputted from the respective unit cells 12-0-12-n is larger, the data is judged to be “1” at the detector 60.

When at a wafer, either of a trimming resistance method that supplies current from the electric power supplying section 71 to the detector 60, or an external reference current applying method that supplies current from the external reference current applying/supplying circuit 75 to the detector 60, can be used. However, after fabrication, the output from the external reference current applying/supplying circuit 75 is not outputted as a pin, and therefore, both at times of user operation and at times of testing, judgment of the data is carried out by the trimming resistance method. The resistance values of the trimming reference technique are a trimming table of trm<0>-<n>, and at the time of the test mode, trm<0>-<n> can be selected and used. Due to any of trm<0>-<n> being selected, any of the corresponding NMOS transistors 74-0-74-n turns on, and the resistance value at the electric power supplying section 71 is determined. In contrast, a trimming table that is set at a fuse is used for the initial values of the user operation.

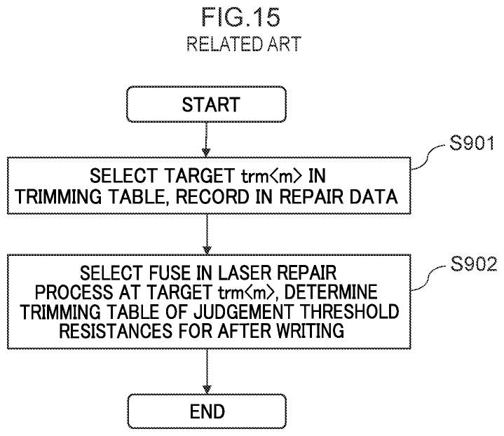

FIG. 15 is a flowchart showing an example of a method of setting a trimming table in the trimming resistance method at the non-volatile memory circuit 9.

First, the target value trm<m> (m is an integer from 0 to n) is selected from among trm<0>-<n> in the trimming table, and trm<m> is recorded in repair data (step S901). Next, a fuse is selected in a laser repair process at the target value trm<m> that was selected in step S901. Then, a trimming table, which selects the resistance for setting the threshold value for judging “0” or “1” after writing to the ZapFuse, is determined (step S902).

However, in the above-described method, the threshold value (judgment threshold value) for judging data at the time of reading the ZapFuse is set at the fuse, and therefore, a laser repair process is needed. Further, even within the same chips within a same wafer, there is dispersion in the resistance values of the ZapFuse after writing, and, at the judgment threshold value of targeting at the time of TEG (Test Element Group) evaluation, the data cannot be judged to be “1” as expected, and the yield decreases in the final test after fabrication. Further, also in cases in which it is judged that the data is “0”, similarly, due to dispersion in the wafer process, in a case in which there exists a ZapFuse whose resistance value is low from before writing, that chip is missed before writing, and, due thereto, yield loss arises.

Detailed examples of non-volatile memory circuits, in which the laser repair process is omitted and in which data can be judged accurately, are described hereinafter.

### First Embodiment

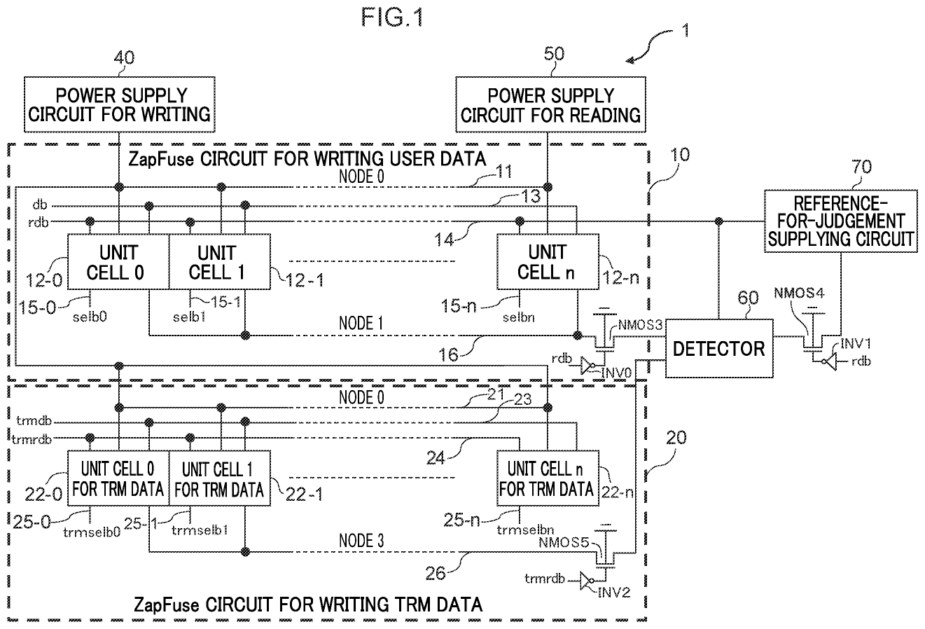

FIG. 1 is a drawing showing an example of the circuit structure of non-volatile memory circuit 1 relating to a first embodiment of the present disclosure.

The non-volatile memory circuit 1 that is shown in FIG. 1 has the power supply circuit 40 for writing, the power supply circuit 50 for reading, the power supply line 11 (also called node 0 hereinafter) for selectively supplying voltage for writing data from the power supplying circuit 40 for writing or voltage for reading data from the power supply circuit 50 for reading, the unit cells 12-1-12-n that are respectively connected in parallel between the power supply line 11 and an unillustrated reference power supply line that is connected to ground level, and that serve as n+1 (n is an integer of 1 or more) storage element portions that store data of 1 bit, the signal lines 13, 14, 15-0-15-n that input respective signals (db, rdb, selb0-selbn), which have been inputted from a control section provided at the exterior, to the respective unit cells 12-0-12-n, the detector 60 to which output currents from the unit cells 12-0-12-n are inputted via the output line (also called node 1 hereinafter) 16 at the time of reading data, an inverting element INV0, an NMOS transistor NMOS3, and the reference-for-judgment supplying circuit 70 that supplies reference current for judgment to the detector 60. The first storage section 10 is structured by the power supply line 11, the unit cells 12-0-12-n, the signal lines 13, 14, 15-0-15-n, the output line 16, the inverting element INV0 and the NMOS transistor NMOS3. The first storage section 10 is a ZapFuse circuit for writing of user data.

Further, the non-volatile memory circuit 1 shown in FIG. 1 has a power supply line 21, unit cells 22-0-22-n that are respectively connected in parallel between the power supply line 21 and an unillustrated reference power supply line that is connected to ground level, and that serve as n+1 (n is an integer of 1 or more) storage element portions that store data of 1 bit, signal lines 23, 24, 25-0-25-n that input respective signals (trmdb, trmrdb, trmselb0-trmselbn), which have been inputted from a control section provided at the exterior, to the respective unit cells 22-0-22-n, an output line (hereinafter also called node 3) 26 that, at the time of reading data, supplies output current from the unit cells 22-0-22-n to the detector 60, an inverting element INV2, and an NMOS transistor NMOS 5. A second storage section 20 is structured by the power supply line 21, the unit cells 22-0-22-n, the signal lines 23, 24, 25-0-25-n, the output line 26, the inverting element INV2 and the NMOS transistor NMOS5. The second storage section 20 is a ZapFuse circuit for TRM data writing. TRM data is data for setting the reference current that is supplied to the detector 60.

In the non-volatile memory circuit 1 shown in FIG. 1, NMOS transistor NMOS4 is connected between the detector 60 and the reference-for-judgment supplying circuit 70. Inverting element INV1 is connected to the gate of the NMOS transistor NMOS 4, and the NMOS transistor NMOS4 switches between on and off in accordance with the state of signal rdb.

Because the unit cells 12-0-12-n are equivalent to the structure of FIG. 13 that was described as related technology, description thereof is omitted. In FIG. 13, the signal that is inputted to each unit cell as db becomes trmdb, and the signal that is inputted to each unit cell as rdb becomes trmrdb, and the signal that is inputted to each unit cell as selbk becomes trmselbk. The operations of writing to the unit cells 22-0-22-n and reading from the unit cells 22-0-22-n can be described by replacing db, rdb, selbk in the description that uses FIG. 13 with trmdb, trmrdb, trmselbk, respectively.

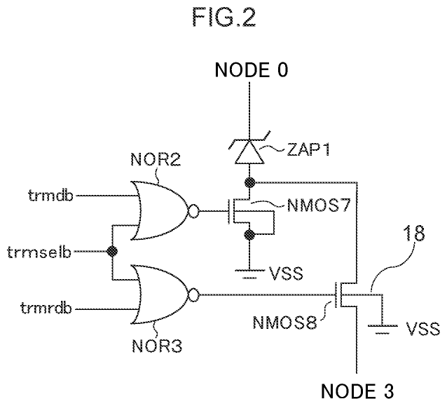

FIG. 2 is a drawing showing a detailed example of the unit cell of the second storage section 20. Each unit cell of the second storage section 20 has a Zener zap element ZAP1 whose cathode is connected to node 0 (the power supply line 21), a transistor NMOS7 that is formed from an NMOS transistor, and that is connected to the anode of the Zener zap element ZAP1, and that, at the time of writing data, connects the Zener zap element ZAP1 to the reference power supply line of reference potential VSS that is ground level, and a transistor NMOS8 that is formed from an NMOS transistor, and that is connected to the anode of the Zener zap element ZAP1, and that, at the time of reading data, connects the Zener zap element ZAP1 to node 3 (the output line 26). The transistor NMOS8 is an example of the switch portion. Moreover, the structure shown in FIG. 2 has NOR circuit NOR2 and NOR circuit NOR3 that control the transistor NMOS7 and the transistor NMOS8 in accordance with the data writing operation and the data reading operation.

The read operation of the Zener zap element ZAP1 is described.

First, H signal is inputted to the terminals db, rdb, selb0-n, trmdb, trmrdb, trmselb0-n of FIG. 1, and the node 0 and the node 1 are made to be ground level. Before the reading operation, selb, db, rdb, trmselb, trmdb, trmrdb in FIG. 1 and FIG. 2 are all H, and therefore, the NOR circuits NOR0, NOR1, NOR2, NOR3, NOR4 all output L, and the transistors NMOS5, NMOS6, NMOS7, NMOS8 are all off.

At the time of reading the Zener zap element ZAP1, L is inputted to trmrdb of FIG. 1. When L is inputted to trmrdb, potential of IVC is supplied to node 0 from the power supply circuit 50 for reading, and potential of around 0.3 V is supplied from the detector 60 to node 3. In this state, in a case in which the unit cell 22-0 is read, trmselb0 in FIG. 1 is L. At the unit cell 22-0, trmselb in FIG. 2 is L, trmdb is H, and trmrdb is L, and therefore, the NOR circuit NOR2 outputs L, and the NOR circuit NOR3 outputs H. Because the NOR circuit NOR2 outputs L, and the NOR circuit NOR3 outputs H, the transistor NMOS7 is off, and the transistor NMOS8 is on. In a case in which the Zener zap element ZAP1 is unwritten (data “0”), current does not flow from node 0 to node 3 due to the resistance of the Zener zap element ZAP1. However, in a case in which the Zener zap element ZAP1 has been written (data “1”), current flows from node 0 to node 3. At this point in time, because trmrdb in FIG. 1 is L, INV2 outputs H. Because INV2 is H, NMOS5 is on. Due to the L input of trmrdb, current flows through the Zener zap element ZAP1 to the detector 60.

Signal rdb is supplied to the inverting elements INV0, INV1. Signal rdb is a signal that has the same function as signal rdb of FIG. 12 and FIG. 13, and is a signal that is L at the time of reading data from the first storage section 10.

Signal trmrdb is supplied to the inverting element INV2. Signal trmrdb is a signal that is L at the time of reading data from the second storage section 20.

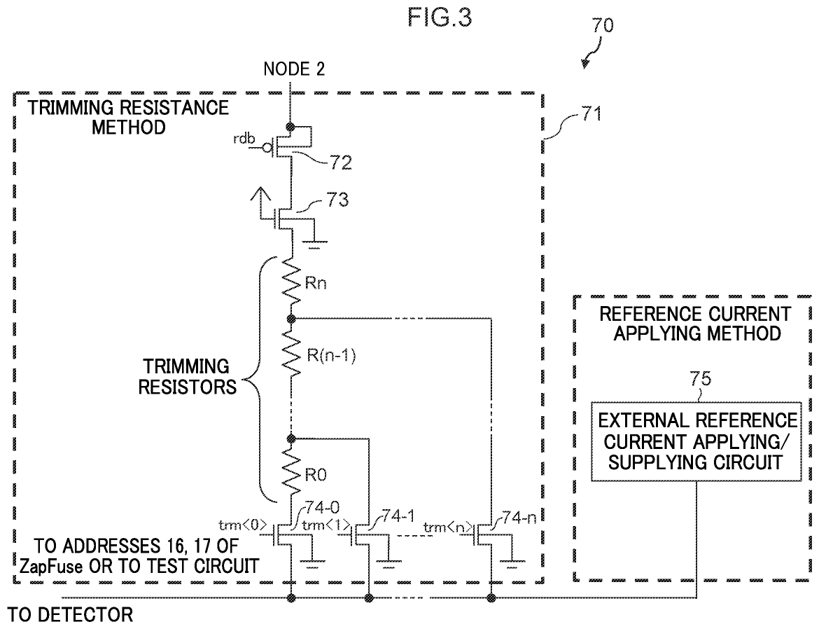

FIG. 3 is a drawing showing an example of the circuit structure of the reference-for-judgment supplying circuit 70. The reference-for-judgment supplying circuit 70 supplies reference current to the detector 60 from the electric power supplying section 71 or the external reference current applying/supplying circuit 75. The electric power supplying section 71 is formed from the PMOS transistor 72, the NMOS transistor 73, the trimming resistors R0-Rn, and the NMOS transistors 74-0-74-n.

The structure of the reference-for-judgment supplying circuit 70 is equivalent to that shown in FIG. 14, but the gates of the NMOS transistors 74-0-74-n are connected such that signals, which are from predetermined addresses of address maps corresponding to storage regions of the first storage section 10 and the second storage section 20, are supplied. In the present embodiment, these predetermined addresses are addresses 16, 17, but the addresses are not limited to this example.

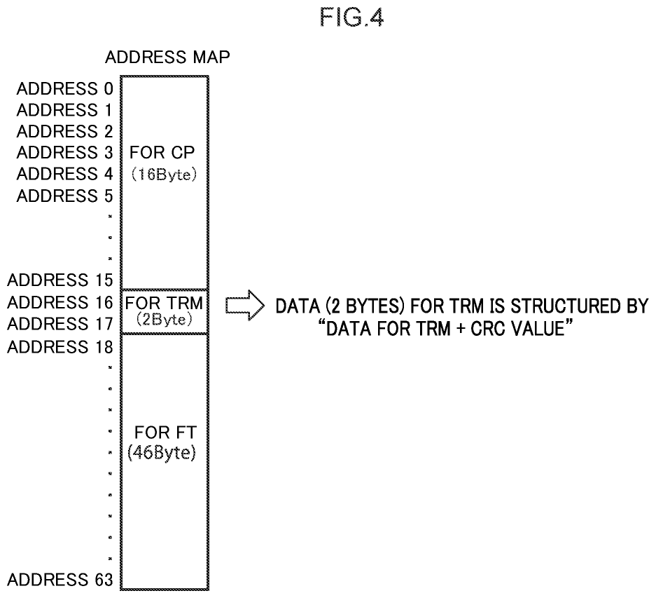

FIG. 4 is a drawing showing an example of the assigning of the address map of the non-volatile memory circuit 1 at which writing is carried out in both a CP (Chip Probing) test when at a wafer, and in a final test after fabrication.

The two bytes of addresses 16, 17 are regions in which are written the trimming table of the judgment threshold values that are set by the fuse in the background art. The data of the trimming table is structured by TRM data+CRC value. Data for determining which of the NMOS transistors 74-0-74-n is to be turned on, i.e., through which of the trimming resistors R0-Rn current from the node 2 is to be supplied to the detector 60, is written to the two bytes of the addresses 16, 17.

Note that the 16 bytes of addresses 0-15 are a region for testing that is for determining a table of trimming resistances of threshold values that judge the “0” or the “1” of the data read from the first storage section 10 at the time of user operation, and are written in a CP test. The 46 bytes of addresses 18-63 are a region in which information for use in the user operation are written, and data are written therein in the final test.

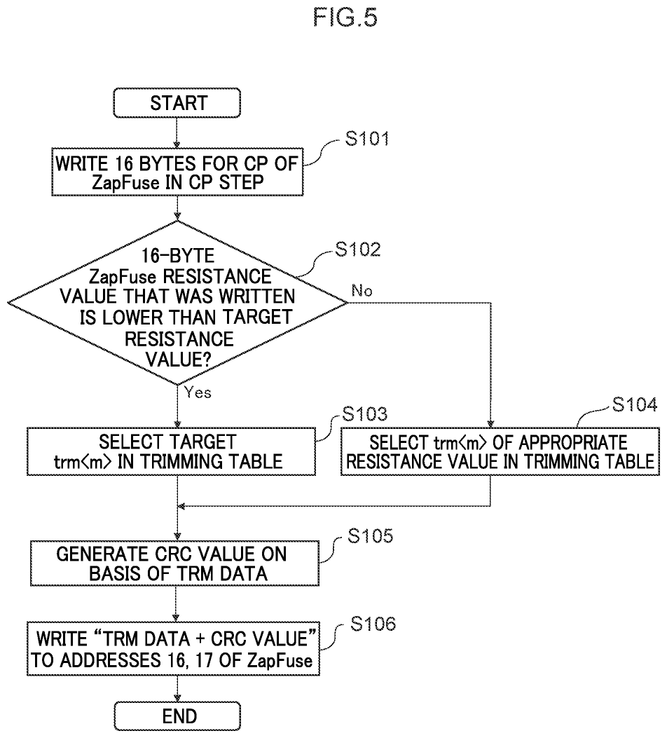

FIG. 5 is a flowchart showing an example of a method of writing TRM data in the non-volatile memory circuit 1.

First, in a CP process of the non-volatile memory circuit 1, writing of the 16 bytes of data for CP of the ZapFuse is carried out (step S101).

Following step S101, it is judged whether or not the ZapFuse resistance value of the 16 bytes that were written is lower than the target resistance value (step S102).

In a case in which the resistance value of the ZapFuse is lower than the target resistance value (step S102: Yes), next, trm<m> that is the target is selected as TRM data from among the trimming table of trm<0>-<n> (step S103).

On the other hand, in a case in which the resistance value of the ZapFuse is greater than or equal to the target resistance value (step S102: No), next, trm<m> that is appropriate as TRM data is selected from among the trimming table of trm<0>-<n> (step S104).

Following step S103 or step S104, a CRC value is generated on the basis of the TRM data (step S105). The generating of the CRC value is carried out at a control section that is provided externally and is not illustrated in FIG. 1.

When the CRC value is generated, the TRM data and the CRC value are written to the addresses 16, 17 of the ZapFuse (step S106).

In the non-volatile memory circuit 1 relating to the present embodiment, for the trimming table of the judgment threshold values, an appropriate trimming table can be selected individually per chip from trimming tables that have been selected by targeting at the time of the TEG evaluation.

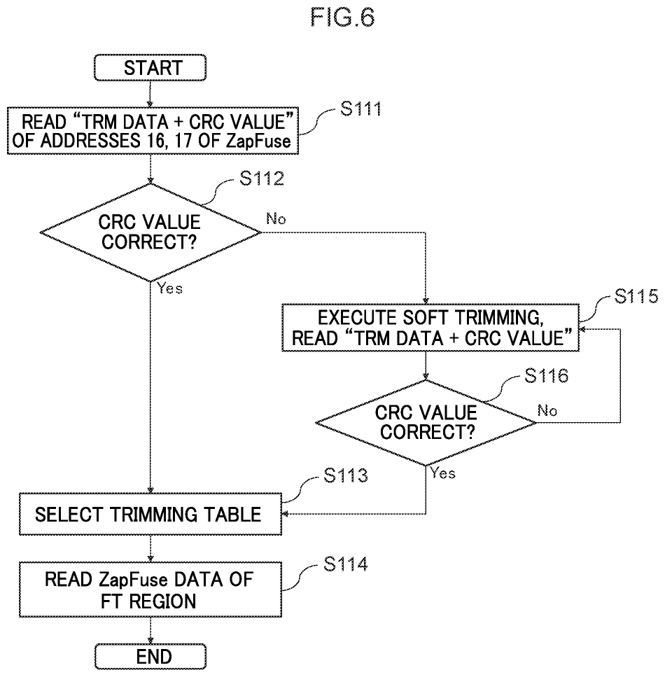

FIG. 6 is a flowchart showing an example of a method of reading user data after writing of TRM data in the non-volatile memory circuit 1.

First, the TRM data and the CRC value that are written in addresses 16, 17 of the ZapFuse are read (step S111).

When the TRM data and the CRC value are read, next, it is judged whether or not a CRC value, which is computed from the TRM data that has been read, and the CRC value that has been read coincide (step S112). The processing of this judgment is carried out at a control section that is provided externally and is not illustrated in FIG. 1.

If, as a result of the judgment of step S112, the CRC value, which is computed from the TRM data that has been read, and the CRC value that has been read coincide (step S112: Yes), next, a trimming table is selected on the basis of the TRM data that has been read (step S113). When the trimming table is selected, next, reading of the data that is written in the ZapFuse in the FT region is carried out by using the trimming resistance set on the basis of the selected trimming table (step S114).

On the other hand, if, as a result of the judgment of step S112, the CRC value, which is computed from the TRM data that has been read, and the CRC value that has been read do not coincide (step S112: No), next, the TRM data and the CRC value are read by executing soft trimming of the threshold value for the data judgment whose object is only the addresses 16, 17 (step S115).

Following step S115, it is judged whether or not the CRC value, which is computed from the TRM data that has been read, and the CRC value that has been read coincide (step S116). The processing of this judgment is carried out at a control section that is provided externally and is not illustrated in FIG. 1.

If, as a result of the judgment of step S116, the CRC value, which is computed from the TRM data that has been read, and the CRC value that has been read coincide (step S116: Yes), reading of the data that is written in the ZapFuse in the FT region is carried out by using the trimming resistance set on the basis of the selected trimming table (step S114). On the other hand, if, as a result of the judgment of step S116, the CRC value, which is computed from the TRM data that has been read, and the CRC value that has been read do not coincide (step S116: No), processing returns to the execution of soft trimming of step S115.

In this way, in the non-volatile memory circuit relating to the first embodiment, a trimming table is selected on the basis of the resistance value of the ZapFuse which was test-written in the CP process, and TRM data and a CRC value are written into the ZapFuse. In the non-volatile memory circuit relating to the first embodiment, the laser repair process is omitted, and, even in a case of a chip at which the resistance value of the ZapFuse after writing is high, the results of reading, in the user operation, the data that has been written in the ZapFuse can be improved.

### Second Embodiment

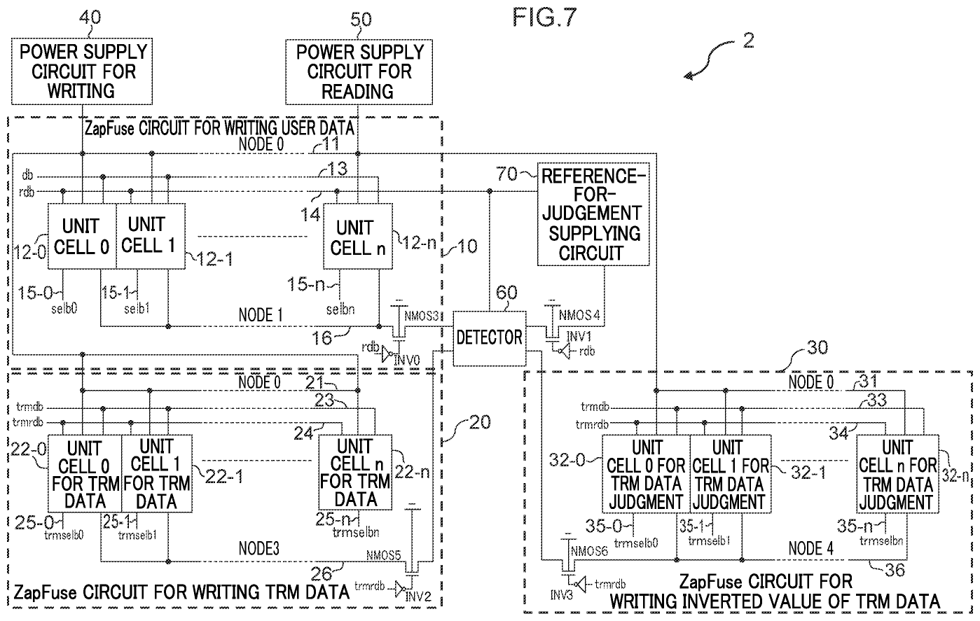

FIG. 7 is a drawing showing an example of the circuit structure of a non-volatile memory circuit 2 relating to a second embodiment of the present disclosure.

The non-volatile memory circuit 2 shown in FIG. 7 is a structure in which a third storage section 30 is added to the non-volatile memory circuit 1 shown in FIG. 1.

The third storage section 30 in the non-volatile memory circuit 2 shown in FIG. 7 has a power supply line 31, unit cells 32-0-32-n that are respectively connected in parallel between the power supply line 31 and an unillustrated reference power supply line that is connected to ground level, and that serve as n+1 (n is an integer of 1 or more) storage element portions that store data of 1 bit, signal lines 33, 34, 35-0-35-n that input respective signals (trmdb, trmrrdb, trmselb0-trmselbn), which have been inputted from a control section provided at the exterior, to the respective unit cells 32-0-32-n, an output line (hereinafter also called node 4) 36 that, at the time of reading data, supplies output current from the unit cells 32-0-32-n to the detector 60, an inverting element INV3, and an NMOS transistor NMOS 6. The third storage section 30 is a ZapFuse circuit for the writing of inverted values of TRM data.

Because the unit cells 12-0-12-n are equivalent to the structure of FIG. 13 that was described as related technology, description thereof is omitted. Further, because the unit cells 22-0-22-n are equivalent to the first embodiment, description thereof is omitted. In FIG. 13, the signal that is inputted to each unit cell as db becomes trmdb, and the signal that is inputted to each unit cell as rdb becomes trmrdb, and the signal that is inputted to each unit cell as selbk becomes trmselbk. The operations of writing to the unit cells 22-0-22-n and the unit cells 32-0-32-n and reading from the unit cells 22-0-22-n and the unit cells 32-0-32-n can be described by replacing db, rdb, selbk in the description that uses FIG. 13 with trmdb, trmrdb, trmselbk, respectively.

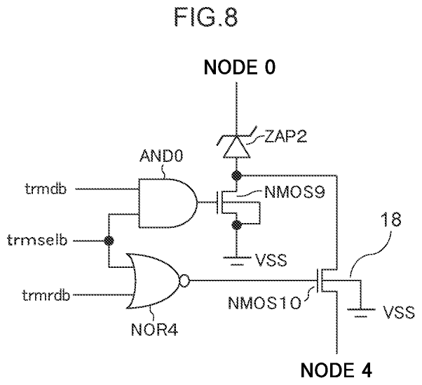

FIG. 8 is a drawing showing a detailed example of the unit cell of the third storage section 30. Each unit cell of the third storage section 30 has a Zener zap element ZAP2 whose cathode is connected to node 0 (the power supply line 31), a transistor NMOS9 that is formed from an NMOS transistor, and that is connected to the anode of the Zener zap element ZAP2, and that, at the time of writing data, connects the Zener zap element ZAP2 to the reference power supply line of reference potential VSS that is ground level, and a transistor NMOS10 that is formed from an NMOS transistor, and that is connected to the anode of the Zener zap element ZAP2, and that, at the time of reading data, connects the Zener zap element ZAP2 to node 4 (the output line 36). The transistor NMOS10 is an example of a switch portion. Moreover, the structure shown in FIG. 8 has the unit cell has AND circuit ANDO and NOR circuit NOR4 that control the transistor NMOS9 and the transistor NMOS10 in accordance with the data writing operation and the data reading operation.

The read operation of the Zener zap element ZAP2 is described.

First, H signal is inputted respectively to the terminals db, rdb, selb0-n, trmdb, trmrdb, trmselb0-n in FIG. 7, and the node 0 and the node 1 are made to be ground level. Before the reading operation, selb, db, rdb, trmselb, trmdb, trmrdb in FIG. 7 and FIG. 2 are all H, and therefore, the NOR circuits NOR0, NOR1, NOR2, NOR3, NOR4 all output L, and the transistors NMOS5, NMOS6, NMOS7, NMOS8 are all off.

Judgment current, for judging “0” or “1” on the basis of the current from the Zener zap element ZAP1, is supplied from the third storage section 30. Because trmselb0 in FIG. 7 is L, at the unit cell 32-0, trmselb in FIG. 8 is H, trmdb is H, and trmrdb is L. Therefore, the AND circuit ANDO outputs L, and the NOR circuit NOR4 outputs H. Because the AND circuit ANDO outputs L, and the NOR circuit NOR4 outputs H, the transistor NMOS9 is off, and the transistor NMOS10 is on. When TRM data is written to the Zener zap element ZAP1 of the unit cell 22-0, the inverted value of that TRM data is written to the unit cell 32-0. In a case in which the Zener zap element ZAP1 of the unit cell 22-0 is unwritten (data “0”), the Zener zap element ZAP2 of the unit cell 32-0 becomes written (“data “1”). In a case in which the Zener zap element ZAP1 of the unit cell 22-0 is written (data “1”), the Zener zap element ZAP2 of the unit cell 32-0 becomes unwritten (“data “0”).

In a case in which the Zener zap element ZAP1 is unwritten, the resistance value of the Zener zap element ZAP1 is high, and current hardly flows at all. In a case in which the Zener zap element ZAP1 is written, the resistance value of the ZapFuse is low as compared with a case in which the Zener zap element ZAP1 is unwritten, and current flows. Due to the above-described characteristic, in a case in which the Zener zap element ZAP1 is written, current flows through the Zener zap element ZAP1 to the detector 60. However, because the Zener zap element ZAP2 that is the judgment current thereof is unwritten, the current that passes from node 0 through the Zener zap element ZAP2 hardly flows at all to the detector 60. Accordingly, on the basis of the current values from the second storage section 20 and the third storage section 30, data “1” is judged at the detector 60. Also in a case in which the Zener zap element ZAP1 is data “0”, similarly, on the basis of the current values from the second storage section 20 and the third storage section 30, data “0” is judged at the detector 60.

Differently than the unit cell that is illustrated in FIG. 2, at the unit cell shown in FIG. 8, at the time of writing data, the AND circuit ANDO is connected to the gate of NMOS9 that connects the Zener zap element ZAP2 to the reference power supply line of reference potential VSS that is ground level.

Signal trmrdb is supplied to the inverting element INV3. Signal trmrdb is a signal that is L at the time of reading data from the second storage section 20 and the third storage section 30.

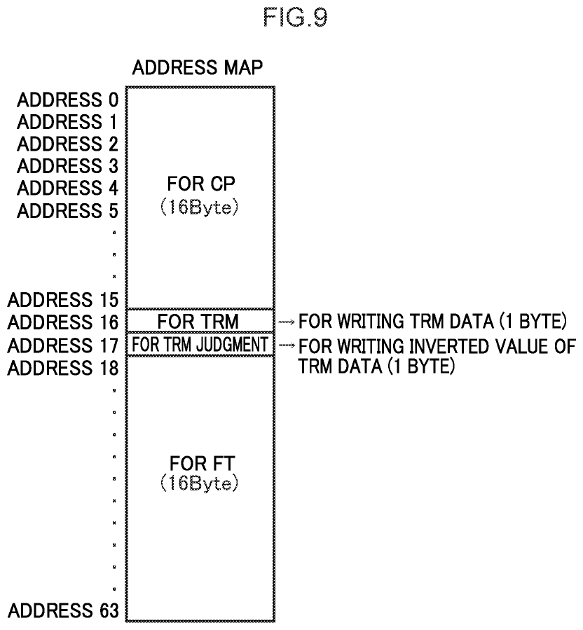

FIG. 9 is a drawing showing an example of the assigning of the address map of the non-volatile memory circuit 2 at which writing is carried out in both a CP (Chip Probing) test when at a wafer, and in a final test after fabrication.

The one byte of address 16 is a region for the writing of the TRM data of the judgment threshold value that is set by the fuse in the background art. The one byte of address 17 is a region for the writing of the inverted value of the TRM data, in order to carry out, as expected, judgment of the TRM data that is for reading, as expected, the TRM data written in address 16.

Note that the 16 bytes of addresses 0-15 are a region for testing that is for determining a table of trimming resistances of threshold values that judge the “0” or the “1” of the data read from the first storage section 10 at the time of user operation, and are written in a CP test. The 46 bytes of addresses 18-63 are a region in which information for use in the user operation are written, and data are written therein in the final test.

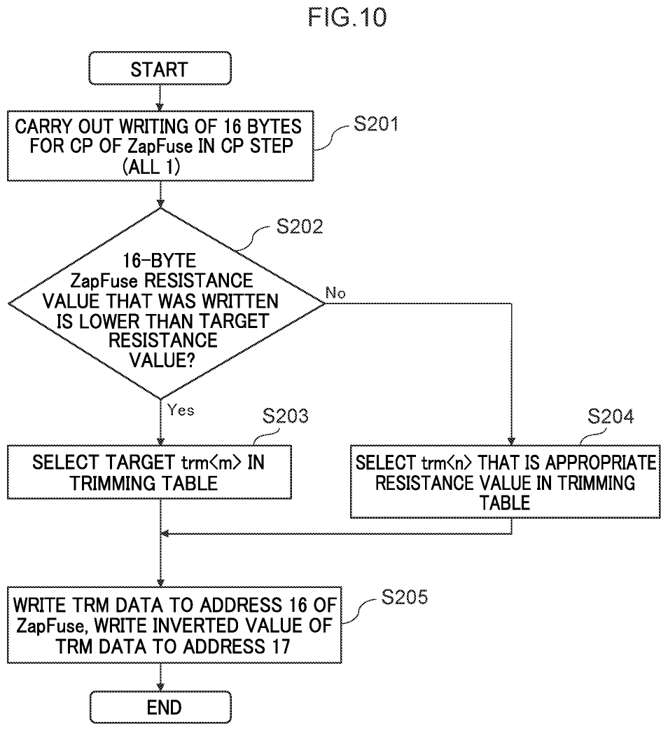

FIG. 10 is a flowchart showing an example of a method of writing TRM data in the non-volatile memory circuit 2.

First, in a CP process of the non-volatile memory circuit 2, writing of the 16 bytes of data for CP of the ZapFuse is carried out (step S201). The data that are written here are all 1.

In step S201, next, it is judged whether or not the ZapFuse resistance value of the 16 bytes that were written is lower than the target resistance value (step S202).

In a case in which the resistance value of the ZapFuse is lower than the target resistance value (step S202: Yes), next, trm<m> that is the target is selected as TRM data from among the trimming table of trm<0>-<n> (step S203).

On the other hand, in a case in which the resistance value of the ZapFuse is greater than or equal to the target resistance value (step S202: No), next, trm<n> that is appropriate as the TRM data is selected from among the trimming table of trm<0>-<n> (step S204).

Following step S203 or step S204, the TRM data is written in address 16 of the ZapFuse, and the inverted value of the TRM data is written in address 17 (step S205).

In the non-volatile memory circuit 2 relating to the present embodiment, for the trimming table of the judgment threshold values, an appropriate trimming table can be selected individually per chip from trimming tables that have been selected by targeting at the time of the TEG evaluation.

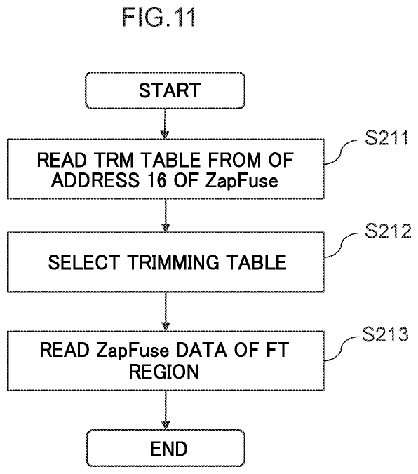

FIG. 11 is a flowchart showing an example of a method of reading user data after writing of TRM data in the non-volatile memory circuit 2.

First, the TRM data that is written in address 16 of the ZapFuse is read (step S211).

Following step S211, a trimming table is selected on the basis of the TRM data read in step S211 and the inverted value thereof (step S212).

Following step S212, reading of the data that is written in the ZapFuse in the FT (Final Test) region is carried out by using a trimming resistance that is set on the basis of the selected trimming table (step S213).

As described above, in the non-volatile memory circuit relating to the second embodiment, a trimming table is selected on the basis of the resistance value of the ZapFuse that was test-written in the CP process, and the TRM data and the inverted value of the TRM data are written in the ZapFuse. In the non-volatile memory circuit relating to the second embodiment, the laser repair process is omitted, and, even in a case of a chip at which the resistance value of the ZapFuse after writing is high, the results of reading, in the user operation, the data that was written into the ZapFuse can be improved.

The non-volatile memory circuit relating to the second embodiment uses the resistance value of the ZapFuse, which is the inverted value of the read data, in the reading judgment of the TRM data that was written in the ZapFuse. Therefore, data of the expected trimming table can be read, without carrying out soft trimming as in the non-volatile memory circuit relating to the first embodiment. Accordingly, in the non-volatile memory circuit relating to the second embodiment, the results of reading, in the user operation, the data that was written into the ZapFuse can be improved.

The logic circuit that includes the NOR circuit NOR0 and the NOR circuit NOR1 is not limited to this structure provided that, on the basis of the signal selbk that selects a unit cell, the logic circuit operates so as to turn the corresponding transistor NMOS0 on at the time of writing, and operates so as to turn the corresponding transistor NMOS1 on at the time of reading.

Further, although the above-described embodiments illustrate non-volatile memory circuits that use a Zener zap element, the non-volatile memory circuits are not limited to using Zener zap elements, provided that they are non-volatile memory circuits having an element whose state changes physically due to the application of voltage from the exterior. Namely, the present disclosure can similarly be applied to non-volatile memory circuits that can write a value due to the state physically changing due to the application of voltage from the exterior or the like.

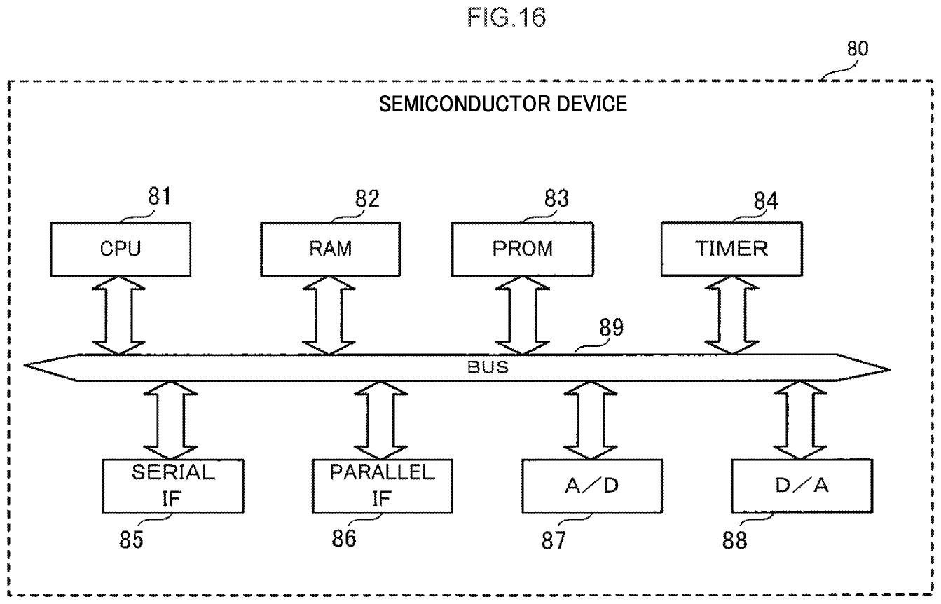

A semiconductor device that uses the non-volatile memory circuit 1, 2 is described next by using FIG. 16.

At semiconductor device 80 shown in FIG. 16, a CPU 81, a RAM 82, a PROM (Programmable Read Only Memory) 83 that is the non-volatile memory circuit relating to an above-described embodiment, a timer (shown as “TIMER” in FIG. 16) 84, a serial interface (shown as “SERIAL IF” in FIG. 16) 85, a parallel interface (shown as “PARALLEL IF” in FIG. 16) 86, an AD converter (shown as “A/D” in FIG. 16) 87, and a DA converter (shown as “D/A” in FIG. 16) 88 are connected via BUS 89.

As an example, the RAM 82 has a capacity of 1024 bytes, and the PROM 83 has a capacity of 60K bytes, or the like. On the basis of control signals from an external device that is connected via the serial interface 85 or the parallel interface 86, the CPU 81 (Central Processing Unit) carries out writing of programs and the like and reading of data with respect to the PROM 83.

This semiconductor device 80 is provided at any of various electronic equipment such as, for example, any of various types of control substrates for autonomous driving control, any of various types of control substrates for manufacturing devices, cell phones, gaming devices and the like.

The present disclosure has been developed in consideration of the above-described points, and has, as the object thereof, the provision of a non-volatile memory circuit, a semiconductor device, and a method of reading a non-volatile memory that can adjust a threshold value that is used in judgment at the time of reading, without using a laser repair process.

A non-volatile memory circuit according to a first aspect of the present disclosure includes a first memory including a plurality of cells that store values by respectively having elements whose states change physically due to application of a voltage from an exterior, a second memory including a plurality of cells that store values by respectively having the elements, a detector that, at a time of reading from the first memory, judges a value stored in each of the cells by comparing a threshold value and current values from the plurality of cells, and a judging circuit supplying current of a predetermined current value to the detector as the threshold value, wherein input terminals of the plurality of cells of the first memory are connected in common so as to be connected to a power supply for writing that supplies a voltage at a time of writing data to the plurality of cells, or a power supply for reading that supplies a voltage at a time of reading data from the plurality of cells, output terminals of the plurality of cells of the first memory are connected in common to an input terminal of the detector that judges a value stored in each of the cells based on current values from the plurality of cells, when reading from the first memory, due to selection instructing signals that select individual cells of the plurality of cells being inputted successively to the input terminals that are included respectively in the plurality of cells at a point in time when a predetermined time period has elapsed from supplying of the voltage of the power supply for reading, the output terminals of the plurality of cells that are selected are connected to the input terminal of the detector, and data, which sets the threshold value that is used in judgment by the detector, is stored in the second memory.

In a non-volatile memory circuit according to a second aspect of the present disclosure according to a first aspect of the present disclosure, the second memory stores, as the data, a selection value for selecting a resistance for causing current of a predetermined current value to flow to the detector as the threshold value, and an inspection value for inspecting the selection value.

A non-volatile memory circuit according to a third aspect of the present disclosure according to a first aspect of the present disclosure, further includes a third memory including a plurality of cells that store values by respectively having the elements, wherein the second memory stores, as the data, a selection value for selecting a resistance for causing current of a predetermined current value to flow to the detector as the threshold value, and wherein the third memory stores an inverted value that is the selection value that has been inverted.

In a non-volatile memory circuit according to a fourth aspect according to a third aspect of the present disclosure, the detector judges the selection value by using the inverted value.

In a non-volatile memory circuit according to a fifth aspect of the present disclosure according to a third aspect of the present disclosure, each cell includes a Zener zap element, and a switch portion that connects an anode of the Zener zap element to an output terminal at a time of reading data.

A semiconductor device according to a sixth aspect of the present disclosure includes a non-volatile memory circuit that includes a first memory including a plurality of cells that store values by respectively having elements whose states change physically due to application of a voltage from an exterior, a second memory including a plurality of cells that store values by respectively having the elements, a detector that, at a time of reading from the first memory, judges a value stored in each of the cells by comparing a threshold value and current values from the plurality of cells, and judging circuit supplying current of a predetermined current value to the detector as the threshold value, wherein input terminals of the plurality of cells of the first memory are connected in common so as to be connected to a power supply for writing that supplies a voltage at a time of writing data to the plurality of cells, or a power supply for reading that supplies a voltage at a time of reading data from the plurality of cells, output terminals of the plurality of cells of the first memory are connected in common to an input terminal of the detector that judges a value stored in each of the cells based on current values from the plurality of cells, when reading from the first memory, due to selection instructing signals that select individual cells of the plurality of cells being inputted successively to the input terminals that are included respectively in the plurality of cells at a point in time when a predetermined time period has elapsed from supplying of the voltage of the power supply for reading, the output terminals of the plurality of cells that are selected are connected to the input terminal of the detector, and data, which sets the threshold value that is used in judgment by the detector, is stored in the second memory, and a processor that carries out either one of or both of reading or writing of data by using the non-volatile memory circuit.

A method of reading a non-volatile memory according to a seventh aspect of the present disclosure includes supplying power for reading to respective input terminals of elements whose states physically change due to application of a voltage from an exterior, a processor selecting a first cell that includes one element, outputting data that is based on information stored in that element, and reading stored information, the processor selecting a second cell that includes one element that is different from the first cell, and outputting data that is based on information stored in that element, the processor setting a threshold value based on the data outputted from the second cell, and the processor judging a value of the data outputted from the first cell, based on the set threshold value.

In accordance with the present disclosure, by storing, in an element, data for setting a threshold value, a threshold value that is used in judgment at the time of reading can be adjusted without using a laser repair process. Further, in accordance with the present disclosure, even in a case in which there is great dispersion in resistance values, yield loss of non-volatile memory circuits can be eliminated by adjusting the threshold value.

What is claimed is:

1. A non-volatile memory circuit comprising:
a first memory including a plurality of cells that store values by respectively having elements whose states change physically due to application of a voltage from an exterior;
a second memory including a plurality of cells that store values by respectively having the elements;
a detector that, at a time of reading from the first memory, judges a value stored in each of the cells by comparing a threshold value and current values from the plurality of cells; and
a judging circuit supplying current of a predetermined current value to the detector as the threshold value,
wherein:
input terminals of the plurality of cells of the first memory are connected in common so as to be connected to a power supply for writing that supplies a voltage at a time of writing data to the plurality of cells, or a power supply for reading that supplies a voltage at a time of reading data from the plurality of cells;
output terminals of the plurality of cells of the first memory are connected in common to an input terminal of the detector that judges a value stored in each of the cells based on current values from the plurality of cells;
when reading from the first memory, due to selection instructing signals that select individual cells of the plurality of cells being inputted successively to the input terminals that are included respectively in the plurality of cells at a point in time when a predetermined time period has elapsed from supplying of the voltage of the power supply for reading, the output terminals of the plurality of cells that are selected are connected to the input terminal of the detector; and
data, which sets the threshold value that is used in judgment by the detector, is stored in the second memory.

2. The non-volatile memory circuit of claim 1, wherein the second memory stores, as the data, a selection value for selecting a resistance for causing current of a predetermined current value to flow to the detector as the threshold value, and an inspection value for inspecting the selection value.

3. The non-volatile memory circuit of claim 1, further comprising:
a third memory including a plurality of cells that store values by respectively having the elements,
wherein the second memory stores, as the data, a selection value for selecting a resistance for causing current of a predetermined current value to flow to the detector as the threshold value, and
wherein the third memory stores an inverted value that is the selection value that has been inverted.

4. The non-volatile memory circuit of claim 3, wherein the detector judges the selection value by using the inverted value.

5. The non-volatile memory circuit of claim 1, wherein each cell includes a Zener zap element, and a switch portion that connects an anode of the Zener zap element to an output terminal at a time of reading data.

6. A semiconductor device comprising:
a non-volatile memory circuit that includes:
a first memory including a plurality of cells that store values by respectively having elements whose states change physically due to application of a voltage from an exterior;
a second memory including a plurality of cells that store values by respectively having the elements;
a detector that, at a time of reading from the first memory, judges a value stored in each of the cells by comparing a threshold value and current values from the plurality of cells; and
a judging circuit supplying current of a predetermined current value to the detector as the threshold value,
wherein:
input terminals of the plurality of cells of the first memory are connected in common so as to be connected to a power supply for writing that supplies a voltage at a time of writing data to the plurality of cells, or a power supply for reading that supplies a voltage at a time of reading data from the plurality of cells;
output terminals of the plurality of cells of the first memory are connected in common to an input terminal of the detector that judges a value stored in each of the cells based on current values from the plurality of cells;
when reading from the first memory, due to selection instructing signals that select individual cells of the plurality of cells being inputted successively to the input terminals that are included respectively in the plurality of cells at a point in time when a predetermined time period has elapsed from supplying of the voltage of the power supply for reading, the output terminals of the plurality of cells that are selected are connected to the input terminal of the detector; and
data, which sets the threshold value that is used in judgment by the detector, is stored in the second memory; and
a processor that carries out either one of or both of reading or writing of data by using the non-volatile memory circuit.

7. A method of reading a non-volatile memory, comprising:
supplying power for reading to respective input terminals of elements whose states physically change due to application of a voltage from an exterior;
a processor selecting a first cell that includes one element, outputting data that is based on information stored in that element, and reading stored information;
the processor selecting a second cell that includes one element that is different from the first cell, and outputting data that is based on information stored in that element;
the processor setting a threshold value based on the data outputted from the second cell; and
the processor judging a value of the data outputted from the first cell, based on the set threshold value.
